(19) United States
(12) Patent Application Publication
(10) Pub. No.: US 2004/0112426 A1
(43) Pub. Date: Jun. 17, 2004

(54) Solar cell and method of manufacturing the same

(75) Inventor: Masato Hagino, Kitakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/731,009

(22) Filed: Dec. 10, 2003

(30) Foreign Application Priority Data
Dec. 11, 2002 (JP) 2002-359676(P)

(51) Int. Cl. H01L 31/00

(52) U.S. Cl. 136/261; 136/256

(57) ABSTRACT

A solar cell includes a dopant diffusion layer formed on the side of a light-receiving surface of a silicon wafer and a light-receiving surface passivation film formed on the dopant diffusion layer. The light-receiving surface passivation film has an opening portion. The solar cell further includes a light-receiving surface electrode formed on the opening portion of the light-receiving surface passivation film. The dopant diffusion layer has a first region covered with the light-receiving surface passivation film and a second region under the opening portion of the light-receiving surface passivation film, and there is a difference between a dopant concentration in the first region and a dopant concentration in the second region. Thus, a solar cell suitable for manufacturing a mass-produced commercial solar battery at low cost and high efficiency as well as a method of manufacturing the same can be provided.

### BACKGROUND OF THE INVENTION

1. Field of the Invention

The present invention relates to a solar cell for photoelectric conversion and a method of manufacturing the same, and more particularly to a solar cell for housing requiring lower costs and higher efficiency and a method of manufacturing the same.

2. Description of the Background Art

Conventional solar cells have been manufactured by dropping a solution containing a dopant (impurity) on a wafer held on a chuck of a spin coater with a light-receiving surface of the wafer facing upward, evenly applying the solution while rotating the wafer at high speed, diffusing the dopant into the wafer in a high temperature furnace to form a PN junction, and applying an electrode paste on the light-receiving surface and a back surface of the wafer by screen-printing, followed by baking, to form an electrode.

A selective emitter structure with a dopant diffusion concentration being higher under a light-receiving surface electrode is proposed in order to improve the junction between the diffusion layer and the electrode (for example, see J. Horzel, et al., “A Simple Processing Sequence for Selective Emitters”, 26th PVSC, IEEE, Sep. 30-Oct. 3, 1997, Anatheim, Calif., USA, pp. 139-142, and J. Horzel et al., “High Efficiency Industrial Screen Printed Selective Emitter Solar Cells”, 16th European Photovoltaic Solar Energy Conference, May 1-5, 2000, Glasgow, UK, pp. 1112-1115).

As a method of fabricating such a selective emitter structure, it is known to mix an impurity serving as a dopant with an electrode paste and diffuse the impurity into a wafer during electrode baking so that the dopant concentration under the electrode is higher than that in the other region. It is also known to apply a paste mixed with an impurity to selectively form a diffusion layer.

The method as described above, however, has not produced cells with characteristics superior to mass-produced, commercial solar cells that are now commercially available. When a paste to be doped with an impurity is applied by screen-printing, it is difficult to form a thin film of a few tens of nm or thinner, and an organic substance and the like as a medium may be left on the surface of the wafer, which may have a negative effect on the characteristics.

When an electrode paste is mixed with an impurity serving as a dopant and the dopant is then diffused in electrode baking, the electric resistance of the electrode itself increases with increasing concentration of the dopant in the electrode paste, leading to degradation of the cell characteristics (in particular, Fill Factor). On the other hand, with reduced dopant concentration, the effect of the selective emitter is hardly obtained, since the electrode baking step is preceded by the diffusion step in the cell manufacturing process and the temperature during the electrode baking must be lower than during the diffusion.

Meanwhile, there have been manufactured solar cells including the selective emitter structure with characteristics superior to mass-produced, commercial solar cells. These cells, however, are not mass-produced as commercial solar cells since they require complicated manufacturing processes and are extremely expensive (see, for example, M. A. Green, “SILICON SOLAR CELLS Advanced Principles & Practice”, Australia, published by Center for Photovoltaic Device and Systems, March 1995, p. 219).

Although the method of manufacturing a selective emitter is theoretically convenient to improve the cell characteristics, the method has not been used to mass-produce cells in which a selective emitter cell structure is intended to be fabricated.

### SUMMARY OF THE INVENTION

It is an object of the present invention to provide a solar cell at low cost and high efficiency that is suitable for manufacturing mass-produced commercial solar batteries, and a method of manufacturing the same.

In order to achieve the aforementioned object, a solar cell in accordance with an aspect of the present invention includes: a dopant diffusion layer formed on a side of a light-receiving surface of a silicon wafer; a light-receiving surface passivation film formed on the dopant diffusion layer, the light-receiving surface passivation film having an opening portion; and a light-receiving surface electrode formed on the opening portion of the light-receiving surface passivation film. The dopant diffusion layer has a first region covered with the light-receiving surface passivation film and a second region under the opening portion of the light-receiving surface passivation film, and there is a difference between a dopant concentration in the first region and a dopant concentration in the second region. Preferably, the light-receiving surface passivation film is any one of a silicon oxide film, an amorphous silicon film, a silicon nitride film, a titanium oxide film, and an aluminum oxide film. Preferably, the opening portion of the light-receiving surface passivation film in the light-receiving surface of the silicon wafer has the same shape and size as a portion where the light-receiving surface electrode is formed, and a selective emitter cell structure is formed where a dopant is diffused at high concentration only in a portion in contact with the light-receiving surface electrode. Alternatively, it is preferable that the opening portion of the light-receiving surface passivation film in the light-receiving surface of the silicon wafer is larger than a portion where the light-receiving surface electrode is formed, whereby even if misalignment occurs in forming the light-receiving surface electrode, the light-receiving surface electrode is formed on a portion where a dopant is diffused at high concentration.

In accordance with another aspect of the present invention, the solar cell as described above further includes a back surface passivation film formed on a back surface of the silicon wafer, and the back surface passivation film has an opening portion. A back surface field layer that is a dopant diffusion layer on a side of the back surface of the silicon wafer is formed at least in a region under the opening portion of the back surface passivation film on the side of the back surface of the silicon wafer. Preferably, the back surface passivation film is any one of a silicon oxide film, an amorphous silicon film, and a silicon nitride film.

In accordance with still another aspect of the present invention, a method of manufacturing a solar cell includes: a step of forming, on a light-receiving surface of a silicon wafer, a light-receiving surface passivation film having an opening portion; and a light-receiving surface dopant diffusion step of forming, on a side of the light-receiving surface of the silicon wafer, a dopant diffusion layer having a difference between a dopant concentration in a first region covered with the light-receiving surface passivation film and a dopant concentration in a second region under the opening portion of the light-receiving surface passivation film. In the light-receiving surface dopant diffusion step, a PN junction is formed by applying an organic solvent solution containing a dopant onto the silicon wafer using a spin coater and introducing the silicon wafer in a furnace to diffuse the dopant into the silicon wafer. Alternatively, a PN junction is formed by diffusing a solution containing a dopant rendered in a gaseous state into the silicon wafer. Alternatively, a PN junction is formed by supplying a dopant into the silicon wafer through ion implantation.

In a method of manufacturing a solar cell in accordance with a further aspect of the present invention, registration of a portion where a dopant is diffused at high concentration with a light-receiving surface electrode is performed at a wafer edge when the light-receiving surface electrode is formed.

In accordance with a still further aspect of the present invention, a method of manufacturing a solar cell includes: a step of forming, on a light-receiving surface of a silicon wafer, a light-receiving surface passivation film having an opening portion; a step of forming, on a back surface of the silicon wafer, a back surface passivation film having an opening portion; a light-receiving surface dopant diffusion step of forming, on a side of the light-receiving surface of the silicon wafer, a dopant diffusion layer having a difference between a dopant concentration in a first region covered with the light-receiving surface passivation film and a dopant concentration in a second region under the opening portion of the light-receiving surface passivation film; and a back surface dopant diffusion step of forming a back surface field layer on a side of the back surface of the silicon wafer. In the back surface dopant diffusion step, a localized back surface field layer structure is formed by applying a paste including aluminum to the back surface of the silicon wafer by screen-printing and introducing the silicon wafer in a furnace, or by diffusing a solution containing a dopant rendered in a gaseous state into the back surface of the silicon wafer, or by supplying a dopant to the back surface of the silicon wafer through ion implantation, to form the back surface field layer only in a region under the opening portion of the back surface passivation film on the side of the back surface of the silicon wafer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a solar cell in accordance with the present invention.

FIG. 2 is a schematic cross-sectional view of another solar cell in accordance with the present invention.

FIGS. 3A-3F are schematic cross-sectional views showing a process of manufacturing a solar cell in accordance with the present invention.

FIGS. 4A-4F are schematic cross-sectional views showing another process of manufacturing a solar cell in accordance with the present invention.

FIGS. 5A-5H are schematic cross-sectional views showing still another process of manufacturing a solar cell in accordance with the present invention.

FIG. 6 is an illustration of spin coating.

FIG. 7 is an illustration of screen-printing.

FIG. 8 is a graph showing the relation between the film thickness of a passivation film and the sheet resistance of a wafer.

### DESCRIPTION OF THE PREFERRED EMBODIMENTS

Referring to FIG. 1, a solar cell in accordance with the present invention includes a dopant diffusion layer 6 formed on the side of a light-receiving surface of a silicon wafer, and a light-receiving surface passivation film 3A formed on dopant diffusion layer 6. Light-receiving surface passivation film 3A has an opening portion 4A. The solar cell further includes a light-receiving surface electrode 8B formed on opening portion 4A. Furthermore, dopant diffusion layer 6 includes a first region 6A covered with light-receiving surface passivation film 3A and a second region 6B under the opening portion 4A of light-receiving surface passivation film 3A. There is a difference between a dopant concentration in first region 6A and a dopant concentration in second region 6B. In other words, a low concentration dopant diffusion layer is formed in first region 6A and a high concentration dopant diffusion layer is formed in second region 6B.

Here, a passivation film refers to a film that is needed for grain boundary passivation, and more specifically to a film having an effect of passivating a surface of a wafer and controlling a dopant concentration in a dopant diffusion layer. Any passivation film may be employed as long as it serves as a barrier against dopant diffusion. A silicon oxide film, an amorphous silicon film, a silicon nitride film, a titanium oxide film, or an aluminum oxide film is preferable. This is because, where electrodes are formed by screen-printing and baking, which are widely used in manufacturing mass-produced commercial solar batteries, the characteristics of such passivation films are not degraded in a high temperature processing step after formation of the passivation film. In addition, the exemplary passivation films as listed above also function as antireflection films and improve the characteristics (in particular, short-circuit current) of solar cells.

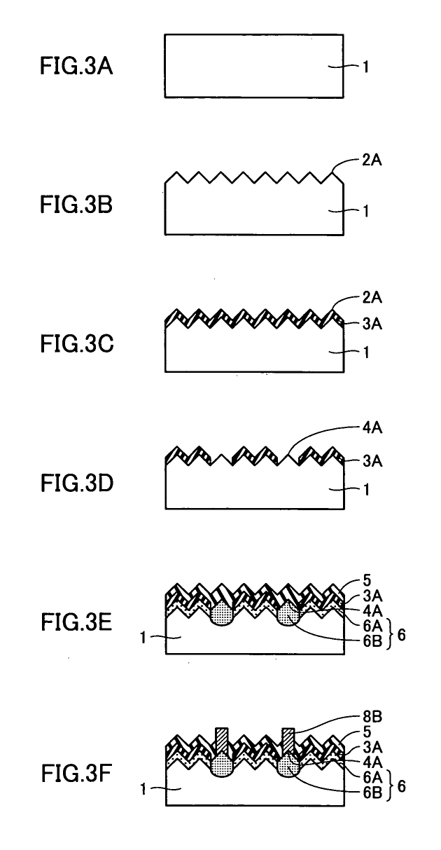

In the case where a silicon oxide film is formed as light-receiving surface passivation film 3A, for example, a silicon wafer 1 is subjected to a heat treatment in an oxygen atmosphere in order to form a silicon oxide film as thin, light-receiving surface passivation film 3A on a texture etching surface 2A that is a light-receiving surface of silicon wafer 1, as shown in FIG. 3C. Using patterned photoresist, the silicon oxide film is partially removed by an aqueous solution of hydrofluoric acid or the like, and the resist is then removed. As shown in FIG. 3D, opening portion 4A of the light-receiving surface passivation film is formed corresponding to the light-receiving surface electrode. In the subsequent dopant diffusion, the silicon oxide film as light-receiving surface passivation film 3A serves as a barrier against dopant diffusion. Therefore, a dopant concentration can be controlled by controlling the thickness of light-receiving surface passivation film 3A. Specifically, as shown in FIG. 3E, a low concentration dopant diffusion layer is formed in first region 6A covered with light-receiving surface passivation film 3A and a high concentration dopant diffusion layer is formed in second region 6B under the opening portion of light-receiving surface passivation film 3A. Furthermore, light-receiving surface electrode 8B is formed in opening portion 4A of the light-receiving surface passivation film, so that a selective emitter structure is formed in which the dopant concentration is high at the portion under the electrode. Therefore, open-circuit voltage of a solar battery is greatly improved and the cell characteristics are improved.

As described above, in the solar cell in accordance with the present invention, it is also preferable to form an amorphous silicon film or a silicon nitride film as a passivation film. Here, an amorphous silicon film can be formed by CVD (Chemical Vapor Deposition) using silane, hydrogen, and the like as a base material. A silicon nitride film can be formed by CVD using silane, ammonia, hydrogen and the like as a base material. The amorphous silicon film and the silicon nitride film are less etched than the silicon oxide film by an acid solution such as hydrofluoric acid. Therefore, a region where an amorphous silicon or silicon nitride film is not to be formed (which corresponds to a region where the light-receiving surface electrode is subsequently formed) is masked before such a film is deposited to form a film pattern.

As described above, in the solar cell in accordance with the present invention, it is also preferable to form a titanium oxide film or an aluminum oxide film as a light-receiving surface passivation film. These films are formed by a vacuum evaporation process, wherein a region where a silicon film is not to be formed (which corresponds to a region where the light-receiving surface electrode is subsequently formed) is masked before the films are deposited to form a film pattern, in a manner similar to the CVD process described above.

Any of the silicon oxide film, amorphous silicon film, silicon nitride film, titanium oxide film, and aluminum oxide film as used as the light-receiving surface passivation film functions to terminate defects in a surface of a silicon wafer and to improve the characteristics of a solar cell (in particular, to improve short-circuit current).

In the solar cell in accordance with the present invention, it is preferable that the opening portion of the light-receiving surface passivation film on the light-receiving surface of the silicon wafer has the same shape and size as a portion where the light-receiving surface electrode is formed, so that a selective emitter structure is formed where a dopant is diffused at high concentration only in a portion in contact with the light-receiving surface electrode. In other words, it is desirable that the light-receiving surface passivation film as mentioned above entirely covers the portion other than the high concentration dopant diffusion layer portion in contact with the light-receiving surface electrode. Preferably, the light-receiving surface passivation film entirely covers the portion not in contact with the electrode (the light-receiving region), because with increasing dopant concentration, the defect density in the dopant diffusion layer increases to cause reduction of short-circuit current, and because the light-receiving surface passivation film also function as an antireflection film.

In the solar cell in accordance with the present invention, it is preferable that the opening portion of the light-receiving surface passivation film on the light-receiving surface of the silicon wafer is slightly larger than the light-receiving surface electrode, whereby even if misalignment occurs in forming the light-receiving surface electrode, the light-receiving surface electrode is formed on a portion where a dopant is diffused at high concentration. If the high concentration dopant diffusion layer is present at a portion other than the light receiving-surface electrode, the defect density in the dopant diffusion layer increases due to the high concentration of dopant and the short-circuit current in the solar cell is reduced due to the reduced lifetime of carriers.

Therefore, most preferably, a pattern of the light-receiving surface electrode and a pattern of the high concentration dopant diffusion portion, (the opening portion of the passivation film) are formed in exactly the same size so that these two patterns perfectly match. In the process of manufacturing commercial solar batteries, which must be performed at low cost, registration is preferably performed using a device capable of accurate position measurement such as a CCD (Charge Coupled Device) camera at the edge of a wafer, rather than using an alignment mark or the like, which would complicate the process and increase the cost. Specifically, a printing device including a CCD camera is used to observe the wafer edge and align the pattern, whereby the amount of misalignment between the pattern of the high concentration dopant diffusion portion and the pattern of the light-receiving surface electrode is reduced as compared with the conventional printing device.

Therefore, in the method of manufacturing a solar cell in accordance with the present invention, it is preferable that registration of the high concentration dopant diffusion portion with the light-receiving surface electrode is performed at the wafer edge in forming the light-receiving surface electrode, in the case of the method without alignment marks as described above. It is noted that the registration may also be performed using an alignment mark formed on the side of light-receiving surface of the silicon wafer during the texture etching or the like.

When the etched wafer as described above is p (n) type monocrystalline silicon, a PN junction is formed by diffusing a Group V (III) dopant. The method of forming a PN junction includes the following three preferable methods, though not limited thereto.

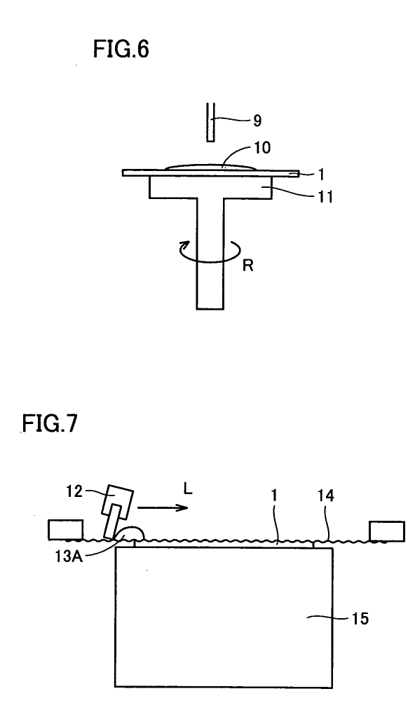

In the first method, a solution containing a dopant is applied on a wafer, and heat treatment is performed to diffuse the dopant. This method is advantageous in that a PN junction and an antireflection film can be formed at the same time by mixing in the solution a dopant for forming the PN junction and a compound of a metal such as titanium whose oxide serves as the antireflection film. The method of applying a solution containing a dopant on a wafer preferably includes spin-coating that allows uniform and efficient application, though the present invention is not limited thereto. In spin-coating, as shown in FIG. 6, a solution 10 containing a dopant is dropped from a solution applying nozzle 9 onto silicon wafer 1 on a spin coater 11 rotating in the direction R, and the solution is uniformly spread by centrifugal force exerted on silicon wafer 1.

In the second method, a solution containing a dopant as a diffusion source is rendered to a gaseous state in a furnace and delivered to a silicon wafer for diffusion. In this method, in the case of a p (n) type silicon wafer, for example, N₂ gas including liquid POCL₃ (BBr₃) is introduced into a furnace so that the dopant is diffused into the wafer. Here, the atmosphere in the furnace is diluted with N₂, O₂ and the like in order to control a dopant partial pressure in the furnace. Alternatively, in the case of a p (n) type silicon wafer, PH₃ (B₂H₆) gas may be diluted with N₂ and the gas may be directly introduced into a furnace for impurity diffusion with the control of the dopant gas concentration.

In the third method, an ionized dopant is directly implanted into a silicon wafer. In this method, in the case of a p (n) type silicon wafer, for example, PH₃ or AsH₃ (B₂H₆) as a diffusion source is introduced into a chamber and is made into a plasma state by arc discharge or the like for ionizing the dopant. Mass separation is performed with application of a magnetic field, and the dopant is implanted into the silicon wafer at an acceleration voltage approximately of a few kV. Here, the atmosphere in the chamber is diluted with H₂, N₂, Ar, and the like. This method is characterized in that a silicon wafer does not need to be heated to a high temperature in implantation. On the other hand, the silicon wafer implanted with ions as described above needs thermal-annealing at 500° C.-850° C., since the wafer suffers dense detects in the surface layer and the implanted ions are not electrically-active impurity.

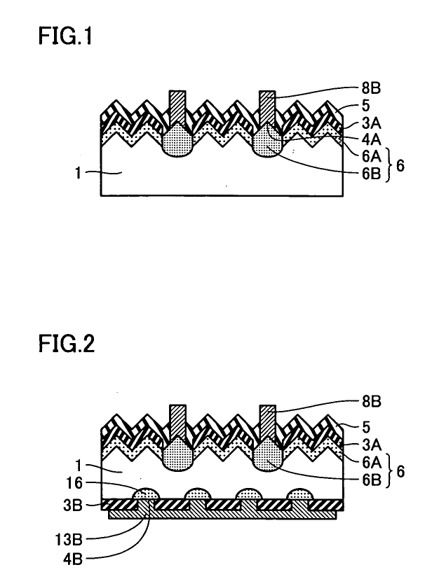

In accordance with the present invention, the solar cell having the light-receiving surface structure as described above further includes a back surface passivation film 3B formed on a back surface of the silicon wafer, as shown in FIG. 2. Back surface passivation film 3B has an opening portion 4B. Furthermore, a back surface field layer 16, which is a dopant diffusion layer on the side of the back surface of the silicon wafer, is formed at least in a region under the opening portion of the back surface passivation film on the side of the back surface of the silicon wafer. The back surface passivation film is preferably formed of a silicon oxide film, an amorphous silicon film or a silicon nitride film.

More specifically, as shown in FIG. 2, the above-noted solar cell has an LBSF (Localized Back Surface Field) layer structure, which is formed by forming a BSF (Back Surface Field) layer 16 only at the opening portion of the passivation film, through solid-phase diffusion, gas-phase diffusion or ion implantation of a Group III (V) element dopant into the p-type (n-type) silicon wafer 1 having back surface passivation film 3B having the opening. Such structure can further improve the characteristics of the solar cell.

Although FIG. 2 shows that back surface field layer 16 is formed in a region not covered with the back surface passivation film, a back surface field layer having a dopant concentration different from that in back surface field layer 16 can also be formed in a region covered with the back surface passivation film in accordance with the present invention.

### First Embodiment

An embodiment of the method of manufacturing a solar cell in accordance with the present invention will specifically be described. A first embodiment is shown in FIGS. 3A-3F. FIGS. 3A-3F illustrate a step of forming on a light-receiving surface of a silicon wafer light-receiving surface passivation film 3A having an opening portion, and a light-receiving surface dopant diffusion step of forming on the side of the light-receiving surface of silicon wafer 1 dopant diffusion layer 6 having a difference between a dopant concentration in first region 6A covered with the passivation film and a dopant concentration in second region 6B under opening portion 4A of light-receiving surface passivation film 3A.

Here, monocrystalline or polycrystalline silicon 125 mm or 155 mm square is used as silicon wafer 1 as shown in FIG. 3A. Any shape or size of wafer may be used since the wafer size does not directly affect the characteristics of the selective emitter.

A p-type silicon wafer is used as such a silicon wafer as in common crystalline silicon solar cells, although an n-type silicon wafer may be used. In the case of monocrystalline silicon, a wafer may be fabricated by any one of CZ (Czochralski) method, MCA (Magnetic Field Applied Czochralski Crystal Growth) method, and FZ (Floating Zone) method. In the case of polycrystalline silicon, thin film polycrystalline silicon may also be used. In either of monocrystalline and polycrystalline silicon, the wafer may have any thickness as long as its mechanical strength is secured. The resistivity of the wafer may be in the range of 0.5 Ω·cm-30 Ω·cm in view of the cell characteristics, although the selective emitter cell may be fabricated with the resistivity outside this range.

In the present embodiment, for example, boron-doped, p-type monocrystalline silicon is used as silicon wafer 1 shown in FIG. 3A.

First, referring to FIG. 3B, silicon wafer 1 is maintained at 75° C.-85° C. and is dipped in an aqueous solution including 1 mass % to 10 mass % of potassium hydroxide or sodium hydroxide and 1 mass % to 10 mass % of isopropyl alcohol as a surfactant, for 10-60 minutes, so that texture etching surface 2A is formed on the light-receiving surface. The texture etching surface may be formed using an aqueous solution of hydrazine or the like. Any method may be used as long as a texture structure that prevents an incident light reflection on the light-receiving surface can be formed.

Next, referring to FIG. 3C, the texture-etched wafer is thermally oxidized in an oxygen atmosphere in a furnace at 800-1000° C., so that a thin silicon oxide film of approximately 3 nm-30 nm thick is formed as light-receiving surface passivation film 3A on the light-receiving surface side of silicon wafer 1.

Then, photoresist (not shown) is spin-coated on the light-receiving surface of the wafer and baking is performed for approximately 20-80 minutes at 70° C.-100° C. A glass mask (not shown) having the same shape as the light-receiving surface electrode pattern is used for exposure and development. The photoresist used herein may be positive or negative. Referring to FIG. 3D, the silicon oxide film is removed only at a portion where the photoresist is removed, by an aqueous solution of 1 mass %-50 mass % of hydrofluoric acid or a mixed aqueous solution of 1 mass %-50 mass % of hydrofluoric acid and ammonium fluoride. Thus, opening portion 4A of light-receiving surface passivation film 3A having the same pattern as the light-receiving surface electrode is formed. The photoresist is thereafter removed completely by dipping in acetone, boiling in sulfuric acid, or the like.

A solution A is uniformly applied to the light-receiving surface of the wafer by a spin coater. Solution A as used here is a solution containing a Group V element, for example, a mixed solution made of phosphorus pentoxide, tetraisopropoxytitanium and isopropylalcohol, for the purpose of diffusing an n-type dopant in p-type monocrystalline silicon. Solution A should be dropped by the amount of 0.3 cm³-5 cm³ for a wafer area of 100 cm². The spin coater rotates at 200-7000 rpm for 1-10 seconds.

Then, the wafer applied with the solution is introduced into a furnace at 800° C.-950° C. to perform n-type dopant diffusion. Referring to FIG. 3E, a low concentration dopant diffusion layer is formed in first region 6A covered with the silicon oxide film as light-receiving surface passivation film 3A, and a high concentration dopant diffusion layer is formed in second region 6B under opening portion 4A of light-receiving surface passivation film 3A.

As a result, the sheet resistance is 10 Ω/□-100 Ω/□ in the opening portion of the silicon oxide film as the light-receiving surface and/or back surface passivation film, whereas the sheet resistance in the region covered with the silicon oxide film is larger than the sheet resistance in the opening portion of the silicon oxide film, accordingly.

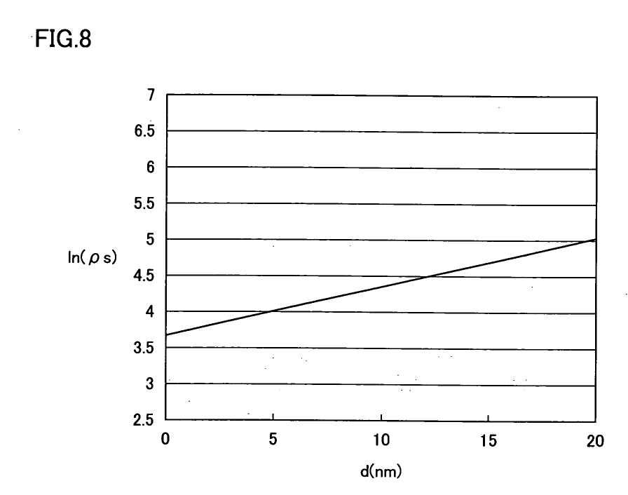

As a film thickness d of the silicon oxide film as the passivation film increases, sheet resistance ps increases, that is, the doping concentration is reduced. FIG. 8 shows the relation between the film thickness and the sheet resistance, by way of example. The straight line in FIG. 8 varies depending on a dopant concentration in a solution, a diffusion temperature, a diffusion time, and a diffusion method (solid-phase diffusion, gas-phase diffusion, or the like).

Solution A contains tetraisopropoxytitanium, which becomes titanium dioxide on the surface of the wafer through the heating process as described above. Therefore, as shown in FIG. 3E, at the same time when the low concentration dopant diffusion layer is formed in first region 6A and the high concentration dopant diffusion layer is formed in second region 6B, titanium dioxide formed on the top of the wafer forms an antireflection film 5.

The antireflection film includes, other than titanium dioxide, aluminum oxide, tin oxide, silicon nitride, tantalum oxide, or the like. A compound containing a metal such as aluminum, tin, tantalum, or the like contained in those oxides may be mixed with solution A, in place of or together with tetraisopropoxytitanium.

Since the antireflection film may be formed after the n-type dopant diffusion, a solution that is not mixed with a metal compound such as tetrapropoxytitanium serving as the antireflection film may be used. For example, in the case of p-type polycrystalline silicon doped with boron, a solution B (for example, a mixed solution made of phosphorous pentoxide and isopropylalcohol) containing a compound of a Group V element such as phosphorous is dropped and uniformly applied on a texture-etched wafer by a spin coater. Then, the wafer is introduced in a furnace for n-type dopant diffusion. Texture etching surface 2A may not necessarily be formed on the wafer surface, since the presence or absence of the texture structure on the wafer surface does not directly affects the selective emitter.

Thereafter, light-receiving surface electrode paste 8A is printed and baked at 500° C.-800° C. to form a light-receiving surface electrode 8B, as shown in FIG. 3F.

### Second Embodiment

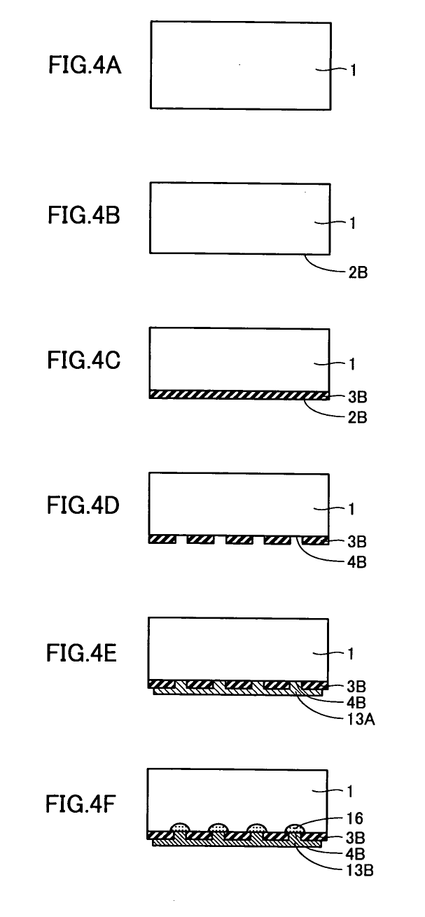

FIGS. 4A-4F show another embodiment of the method of manufacturing a solar cell in accordance with the present invention. FIGS. 4A-4F illustrate a step of forming on the back surface of silicon wafer 1 back surface passivation film 3B having an opening portion, and a back surface dopant diffusion step of forming back surface field layer 16 at least in a region under opening portion 4B of back surface passivation film 3B on the side of the back surface of silicon wafer 1.

In the case of p-type monocrystalline silicon doped with boron, for example, as shown in FIG. 4B, the back surface of silicon wafer 1 is etched to form an etching surface 2B. Thereafter, thermal oxidation is performed in an oxygen or water vapor atmosphere in a furnace at 800° C.-1000° C. to form a silicon oxide film of 10 nm-500 nm as back surface passivation film 3B on the back surface of silicon wafer 1, as shown in FIG. 4C.

Then, photoresist (not shown) is spin-coated on the back surface (the surface opposite to the light-receiving surface) of the wafer and baking is performed at 70° C.-100° C. for 20-80 minutes. A glass mask (not shown) having a prescribed pattern is used for exposure and development. The photoresist used herein may be positive or negative. In the patterned wafer, the silicon oxide film is removed only at a portion where the photoresist is removed, by an aqueous solution of 1 mass %-50 mass % of hydrofluoric acid or a mixed solution of 1 mass %-50 mass % of hydrofluoric acid and ammonium fluoride, and opening portion 4B of back surface passivation film 3B is formed. The resist is completely removed by dipping in acetone, boiling in sulfuric acid, or the like, resulting in the wafer as shown in FIG. 4D.

Such back surface passivation film 3B may be an amorphous silicon film or a silicon nitride film, in place of the silicon oxide film as described above. In this case, an amorphous silicon film or a silicon nitride film is deposited at a required region by plasma CVD using a prescribed metal mask (not shown).

In the case of a p-type (n-type) silicon wafer, an LBSF (Localized Back Surface Field) layer structure can be formed in the wafer having a pattern of the back surface passivation film 3B on the back surface, where BSF (Back Surface Field) layer 16 is formed only in a region under opening portion 4B of back surface passivation film 3B through solid-phase diffusion, gas-phase diffusion or ion implantation of a dopant of a Group III (V) element.

For example, as shown in FIG. 4E, aluminum as a dopant is diffused only in the region under opening portion 4B of back surface passivation film 3B by printing aluminum paste as back surface electrode paste 13A on the entire back surface including opening portion 4B of the back surface passivation film, followed by baking at approximately 550° C.-800° C. Thus, back surface field layer 16 is locally formed as shown in FIG. 4F. The electrode paste as used herein includes aluminum, silver, or the like. Aluminum is a p-type dopant for silicon and is used on the back surface to form the back surface field layer, in the case of p-type crystal.

In printing the electrode paste, the following screen printing is preferably used, though not limited thereto. For example, as shown in FIG. 7, printing is preferably performed by using a squeeze 12 to squeeze back surface electrode paste 13A out of an opening of a screen 14 onto the back surface of silicon wafer 1 placed on a printing table 15.

### Third Embodiment

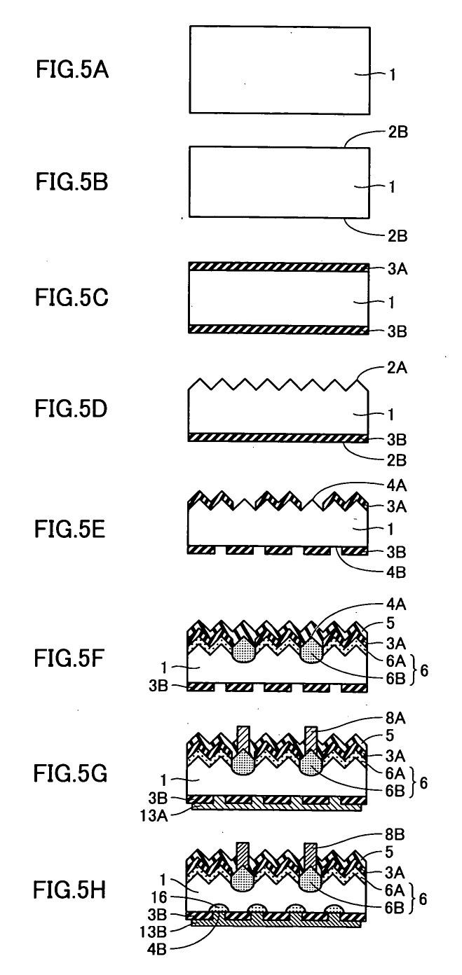

FIGS. 5A-5H show still another embodiment of the method of manufacturing a solar cell in accordance with the present invention. There is shown a manufacturing step of forming a selective emitter on the light-receiving surface and a localized back surface field layer on the back surface at the same time.

In the case of p-type monocrystalline silicon doped with boron, for example, the light-receiving surface and the back surface of silicon wafer 1 are etched to form etching surfaces 2B, as shown in FIG. 5B. Thermal oxidization is thereafter performed in an oxygen or water vapor atmosphere in a furnace at 800° C.-1000° C. to form silicon oxide films of approximately 10 nm-500 nm as light-receiving surface passivation film 3A and back surface passivation film 3B on the surfaces of the wafer, as shown in FIG. 5C.

Then, as shown in FIG. 5D, only the silicon oxide film as light-receiving surface passivation film 3A on the side on which a texture surface is to be formed is removed. Silicon wafer 1 is kept at approximately 75° C.-85° C. and dipped in an aqueous solution including 1 mass %-10 mass % of potassium hydroxide or sodium hydroxide and 1 mass %-10 mass % of isopropylalcohol as a surfactant, for 10-60 minutes, so that texture etching surface 2A is formed on the light-receiving surface. The texture-etched wafer is then thermally oxidized in an oxygen atmosphere in a furnace at 800° C.-1000° C. so that a thin silicon oxide film of 3 nm-30 nm thick is formed as light-receiving surface passivation film 3A on the light-receiving surface of silicon wafer 1.

Then, photoresist (not shown) is spin-coated on the light-receiving and back surfaces of silicon wafer 1 and baking is performed at 70° C.-100° C. for 20-80 minutes. A glass mask (not shown) having a prescribed pattern is used for exposure and development. Here, in the exposure on the side of light-receiving surface, a glass mask (not shown) having the same shape as the light-receiving surface electrode pattern is preferably used, as described above. The photoresist used herein may be positive or negative. In the patterned wafer, the silicon oxide film is removed only at a portion where the photoresist is removed, by an aqueous solution of 1 mass %-50 mass % of hydrofluoric acid or a mixed aqueous solution of 1 mass %-50 mass % of hydrofluoric acid and ammonium fluoride, and the opening portions 4A, 4B of light-receiving surface and back surface passivation films 3A, 3B are formed. The photoresist is completely removed by dipping in acetone, boiling in sulfuric acid, or the like, resulting in the wafer as shown in FIG. 5E.

Solution A is uniformly applied to the light-receiving surface of the wafer by a spin coater. Solution A as used herein is a solution containing a Group V element, for example, a mixed solution made of phosphorous pentoxide, tetraisopropoxytitanium and isopropylalcohol, for the purpose of n-type dopant diffusion in p-type monocrystalline silicon. The conditions of the amount of solution A to be dropped, the rotation number of the spin coater, and the like are similar as described in the first embodiment.

Then, the wafer applied with the solution is introduced into a furnace at 800° C.-950° C. to perform n-type dopant diffusion. Referring to FIG. 5F, a low concentration dopant diffusion layer is formed in first region 6A covered with light-receiving surface passivation film 3A and a high concentration dopant diffusion layer is formed in second region 6B under opening portion 4A of light-receiving surface passivation film 3A. Since solution A includes tetraisopropoxytitanium, antireflection film 5 made of titanium dioxide is formed on the top surface of the wafer, at the same time when the low concentration dopant diffusion layer is formed in first region 6A and the high concentration dopant diffusion layer is formed in second region 6B, as described in the first embodiment.

Referring to FIG. 5G, electrode paste (light-receiving surface electrode paste 8A and back surface electrode paste 13A) is screen-printed on the light-receiving surface and the back surface of the wafer, and baking is performed at 500° C.-800° C. Therefore, as shown in FIG. 5H, light-receiving surface electrode 8B and back surface electrode 13B are formed, and in addition, back surface field layer 16 is formed only in the region under opening portion 4B of back surface passivation film 3B.

The solar cell in accordance with the present invention has a n⁺⁺/n⁺/silicon (p⁻)/p⁺ structure, in the case of p-type silicon in the third embodiment, where the open-circuit voltage is 10 mV-20 mV higher than that of the conventional p-type silicon solar cell (n⁺/silicon (p⁻)/p⁺ structure). Furthermore, the Fill Factor is improved by a few percent since the contact with the light-receiving surface electrode is improved. In addition, the passivation of the surface terminates defects in the vicinity of the surface and reduces recombination of carriers in the vicinity of the light-receiving surface, so that short-circuit current is increased by a few percent. As a result, when CZ-type monocrystalline silicon of a mass-produced size is used, the conversion efficiency of the solar cell is considerably improved from 17% to 19%.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar cell comprising:
a dopant diffusion layer formed on a side of a light-receiving surface of a silicon wafer;
a light-receiving surface passivation film formed on said dopant diffusion layer, said light-receiving surface passivation film having an opening portion; and
a light-receiving surface electrode formed on the opening portion of said light-receiving surface passivation film, wherein
said dopant diffusion layer has a first region covered with said light-receiving surface passivation film and a second region under the opening portion of said light-receiving surface passivation film, and there is a difference between a dopant concentration in said first region and a dopant concentration in said second region.

2. The solar cell according to claim 1, wherein
said light-receiving surface passivation film is any one of a silicon oxide film, an amorphous silicon film, a silicon nitride film, a titanium oxide film, and an aluminum oxide film.

3. The solar cell according to claim 1, wherein
the opening portion of said light-receiving surface passivation film in the light-receiving surface of the silicon wafer has the same shape and size as a portion where said light-receiving surface electrode is formed, and a selective emitter cell structure is formed where a dopant is diffused at high concentration only in a portion in contact with said light-receiving surface electrode.

4. The solar cell according to claim 1, wherein
the opening portion of said light-receiving surface passivation film in the light-receiving surface of the silicon wafer is larger than a portion where said light-receiving surface electrode is formed, whereby even if misalignment occurs in forming said light-receiving surface electrode, said light-receiving surface electrode is formed on a portion where a dopant is diffused at high concentration.

5. The solar cell according to claim 1, further comprising a back surface passivation film formed on a back surface of said silicon wafer, said back surface passivation film having an opening portion, wherein
a back surface field layer that is a dopant diffusion layer on a side of the back surface of said silicon wafer is formed at least in a region under the opening portion of said back surface passivation film on the side of the back surface of said silicon wafer.

6. The solar cell according to claim 5, wherein
said back surface passivation film is any one of a silicon oxide film, an amorphous silicon film, and a silicon nitride film.

7. A method of manufacturing a solar cell, comprising:
a step of forming, on a light-receiving surface of a silicon wafer, a light-receiving surface passivation film having an opening portion; and
a light-receiving surface dopant diffusion step of forming, on a side of the light-receiving surface of said silicon wafer, a dopant diffusion layer having a difference between a dopant concentration in a first region covered with said light-receiving surface passivation film and a dopant concentration in a second region under the opening portion of said light-receiving surface passivation film, wherein
in said light-receiving surface dopant diffusion step, a PN junction is formed by applying an organic solvent solution containing a dopant onto the silicon wafer using a spin coater and introducing said silicon wafer in a furnace to diffuse the dopant into said silicon wafer.

8. The method of manufacturing a solar cell according to claim 7, wherein
said organic solvent solution containing a dopant is an organic solvent solution containing a dopant and titanium.

9. A method of manufacturing a solar cell, comprising:
a step of forming, on a light-receiving surface of a silicon wafer, a light-receiving surface passivation film having an opening portion; and
a light-receiving surface dopant diffusion step of forming, on a side of the light-receiving surface of said silicon wafer, a dopant diffusion layer having a difference between a dopant concentration in a first region covered with said light-receiving surface passivation film and a dopant. concentration in a second region under the opening portion of said light-receiving surface passivation film, wherein
in said light-receiving surface dopant diffusion step, a PN junction is formed by diffusing a solution containing a dopant rendered in a gaseous state into the silicon wafer.

10. A method of manufacturing a solar cell, comprising:
a step of forming, on a light-receiving surface of a silicon wafer, a light-receiving surface passivation film having an opening portion; and
a light-receiving surface dopant diffusion step of forming, on a side of the light-receiving surface of said silicon wafer, a dopant diffusion layer having a difference between a dopant concentration in a first region covered with said light-receiving surface passivation film and a dopant concentration in a second region under the opening portion of said light-receiving surface passivation film, wherein
in said light-receiving surface dopant diffusion step, a PN junction is formed by supplying a dopant into the silicon wafer through ion implantation.

11. A method of manufacturing a solar cell, comprising:
a step of forming, on a light-receiving surface of a silicon wafer, a light-receiving surface passivation film having an opening portion;
a step of forming, on a back surface of said silicon wafer, a back surface passivation film having an opening portion;
a light-receiving surface dopant diffusion step of forming, on a side of the light-receiving surface of said silicon wafer, a dopant diffusion layer having a difference between a dopant concentration in a first region covered with said light-receiving surface passivation film and a dopant concentration in a second region under the opening portion of said light-receiving surface passivation film; and
a back surface dopant diffusion step of forming a back surface field layer on a side of the back surface of said silicon wafer, wherein
in said back surface dopant diffusion step, a localized back surface field layer structure is formed by applying a paste including aluminum to the back surface of said silicon wafer by screen-printing and introducing said silicon wafer in a furnace to form the back surface field layer only in a region under the opening portion of said back surface passivation film on the side of the back surface of said silicon wafer.

12. A method of manufacturing a solar cell, comprising:
a step of forming, on a light-receiving surface of a silicon wafer, a light-receiving surface passivation film having an opening portion;
a step of forming, on a back surface of said silicon wafer, a back surface passivation film having an opening portion;
a light-receiving surface dopant diffusion step of forming, on a side of the light-receiving surface of said silicon wafer, a dopant diffusion layer having a difference between a dopant concentration in a first region covered with said light-receiving surface passivation film and a dopant concentration in a second region under the opening portion of said light-receiving surface passivation film; and
a back surface dopant diffusion step of forming a back surface field layer on a side of the back surface of said silicon wafer, wherein
in said back surface dopant diffusion step, a localized back surface field layer structure is formed by diffusing a solution containing a dopant rendered in a gaseous state into the back surface of said silicon wafer to form the back surface field layer only in a region under the opening portion of said back surface passivation film on the side of the back surface of said silicon wafer.

13. A method of manufacturing a solar cell, comprising:
a step of forming, on a light-receiving surface of a silicon wafer, a light-receiving surface passivation film having an opening portion;
a step of forming, on a back surface of said silicon wafer, a back surface passivation film having an opening portion;
a light-receiving surface dopant diffusion step of forming, on a side of the light-receiving surface of said silicon wafer, a dopant diffusion layer having a difference between a dopant concentration in a first region covered with said light-receiving surface passivation film and a dopant concentration in a second region under the opening portion of said light-receiving surface passivation film; and
a back surface dopant diffusion step of forming a back surface field layer on a side of the back surface of said silicon wafer, wherein
in said back surface dopant diffusion step, a localized back surface field layer structure is formed by supplying a dopant to the back surface of said silicon wafer through ion implantation to form the back surface field layer only in a region under the opening portion of said back surface passivation film on the side of the back surface of said silicon wafer.
